(19) United States
(12) Patent Application Publication
(10) Pub. No.: US 2008/0124937 A1
(43) Pub. Date: May 29, 2008

(54) Selective etching method and apparatus

(76) Inventors: Songlin Xu, Fremont, CA (US); Ce Qin, Fremont, CA (US)

Correspondence Address: PRITZKAU PATENT GROUP, LLC, 993 GAPTER ROAD, BOULDER, CO, 80303, US

(21) Appl. No.: 11/506,173

(22) Filed: Aug. 16, 2006

(51) Int. Cl. H01L 21/3065

(52) U.S. Cl. 438/724; 257/E21.218

(57) ABSTRACT

A dry etching method and apparatus are described. A workpiece supports silicon nitride and silicon dioxide. The workpiece is exposed to a plasma containing at least one of sulfur hexafluoride and nitrogen trifluoride and ammonia to selectively remove the silicon nitride in relation to the silicon dioxide. In one feature, the plasma contains sulfur hexafluoride and ammonia. In another feature, the plasma contains nitrogen trifluoride and ammonia.

### BACKGROUND

The present invention is related generally to the field of selective etching using a plasma and, more particularly, to selectively etching silicon nitride in the presence of silicon dioxide and an associated apparatus.

The formation, for example, of modern integrated circuits can require many process steps. In the manufacture of some state-of-the-art integrated circuits, there is a need to selectively remove silicon nitride in the presence of silicon dioxide. In some cases, a layer of silicon dioxide may support an overlying layer of silicon nitride where it is desired to remove the silicon nitride in selected regions, whereby to expose the underlying silicon dioxide without causing significant damage to the silicon dioxide. One example of a situation in which this need arises resides in silicon nitride gate spacer etching where, at one point in the process, a silicon nitride layer surrounds a gate electrode that is itself supported on a gate silicon dioxide layer. The objective is to remove the silicon nitride from the gate silicon dioxide layer which surrounds the gate electrode, without significantly damaging the gate silicon dioxide layer.

Another example of this situation is seen in the formation of a floating gate electrode in an ONO (Oxide Nitride Oxide) film stack used in flash memory. Typically, an EEPROM device includes a floating-gate electrode upon which electrical charge is stored. In a flash EEPROM device, electrons are transferred to a floating-gate electrode through a dielectric layer overlying the channel region of the transistor. The ONO structure is in wide use in state-of-the-art non-volatile memory devices. At one point during formation of the floating gate structure, a substrate supports a silicon dioxide, silicon nitride, silicon dioxide (i.e., ONO) layer structure. A gate electrode is supported on this ONO layer structure. In particular, the gate electrode is located directly on an outer layer of silicon dioxide. Initially, the outer layer of silicon dioxide, surrounding the gate electrode, is removed. This exposes the inner, silicon nitride layer which is itself supported on a bottom layer of silicon dioxide that is supported directly on the substrate. At this point, the silicon nitride layer, surrounding the gate electrode, must be removed to expose the underlying, bottom layer of silicon dioxide, but without adversely affecting the bottom layer of silicon dioxide.

Having set forth several examples of processing scenarios in which it is necessary to selectively remove silicon nitride in the presence of silicon dioxide, the state-of-the-art will now be considered, as it addresses this need. Turning to FIG. 1, one recent approach that has been used for the purpose of selectively removing silicon nitride, relative to silicon dioxide uses a plasma that is formed from sulfur hexafluoride (SF₆) and Hydrogen (H₂). This prior art process is illustrated by way of a plot 1 of silicon nitride to silicon dioxide selectivity versus hydrogen gas flow. Process conditions include a pressure of 20 millitorr, 1000 watts of RF power applied to the plasma source, no power applied to the wafer pedestal, a 30 sccm flow of SF₆, a 170 sccm flow of Argon, a process temperature of 25 degrees Centigrade and a process time of 30 seconds. While the combination of SF₆ and H₂ gas has demonstrated acceptable selectivity, as can be seen from the plot of FIG. 1, the use of hydrogen gas can be a significant concern at least with respect to its flammability.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods which are meant to be exemplary and illustrative, not limiting in scope. In various embodiments, one or more of the above-described limitations have been reduced or eliminated, while other embodiments are directed to other improvements.

A dry etching method and associated apparatus are described. In one aspect of the present disclosure, a workpiece supports silicon nitride and silicon dioxide. The workpiece is exposed to a plasma containing (i) at least a selected one of sulfur hexafluoride and nitrogen trifluoride and (ii) ammonia to selectively remove the silicon nitride in relation to the silicon dioxide. In one feature, the plasma contains sulfur hexafluoride and ammonia. In another feature, the plasma contains nitrogen trifluoride and ammonia.

In another aspect of the present disclosure, a dry etching system is configured for selective etching of silicon nitride in the presence of silicon dioxide. The system includes a chamber defining a chamber interior. A workpiece support arrangement supports a workpiece in the chamber interior. The workpiece supports silicon nitride and silicon dioxide. A plasma generator is configured for producing a plasma containing (i) at least a selected one of sulfur hexafluoride and nitrogen trifluoride and (ii) ammonia and for exposing the workpiece to the plasma to selectively remove the silicon nitride in relation to the silicon dioxide. In one feature, the plasma generator is configured to produce the plasma containing sulfur hexafluoride and ammonia. In another feature, the plasma generator is configured to produce the plasma containing nitrogen trifluoride and ammonia.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be illustrative rather than limiting.

FIG. 1 is a plot of process results for a prior art process for use in selective removal of silicon nitride with respect to silicon dioxide.

FIG. 2 is a diagrammatic view, in elevation, of a system that is configured for selective removal of silicon nitride in the presence of silicon dioxide.

FIG. 3 illustrates silicon nitride to silicon dioxide selectivity versus flow of ammonia (NH₃) gas and includes a plot of the selectivity that is obtained with the use of the combination of sulfur hexafluoride and ammonia as well as a plot of the selectivity that is obtained with the use of the combination of nitrogen trifluoride and ammonia.

FIG. 4 illustrates silicon nitride to silicon dioxide selectivity versus process pressure gas and includes two plots of the selectivity that is obtained with the use of the combination of sulfur hexafluoride, ammonia and argon as well as a plot of the selectivity that is obtained with the use of the combination of sulfur hexafluoride and argon.

FIG. 5 illustrates silicon nitride to silicon dioxide selectivity versus process pressure gas and includes one plot of the selectivity that is obtained with the use of the combination of nitrogen trifluoride, ammonia and argon as well as another plot of the selectivity that is obtained with the use of the combination of nitrogen trifluoride and argon.

### DETAILED DESCRIPTION

The following description is presented to enable one of ordinary skill in the art to make and use the invention and is provided in the context of a patent application and its requirements. Various modifications to the described embodiments will be readily apparent to those skilled in the art and the generic principles taught herein may be applied to other embodiments. Thus, the present invention is not intended to be limited to the embodiment shown but is to be accorded the widest scope consistent with the principles and features described herein including alternatives, modifications and equivalents, as defined within the scope of the appended claims. It is noted that the drawings are not to scale and are diagrammatic in nature in a way that is thought to best illustrate features of interest. Further, like reference numbers are applied to like components, whenever practical, throughout the present disclosure. Descriptive terminology such as, for example, upper/lower, right/left, front/rear and the like may be adopted for purposes of enhancing the reader's understanding, with respect to the various views provided in the figures, and is in no way intended as being limiting.

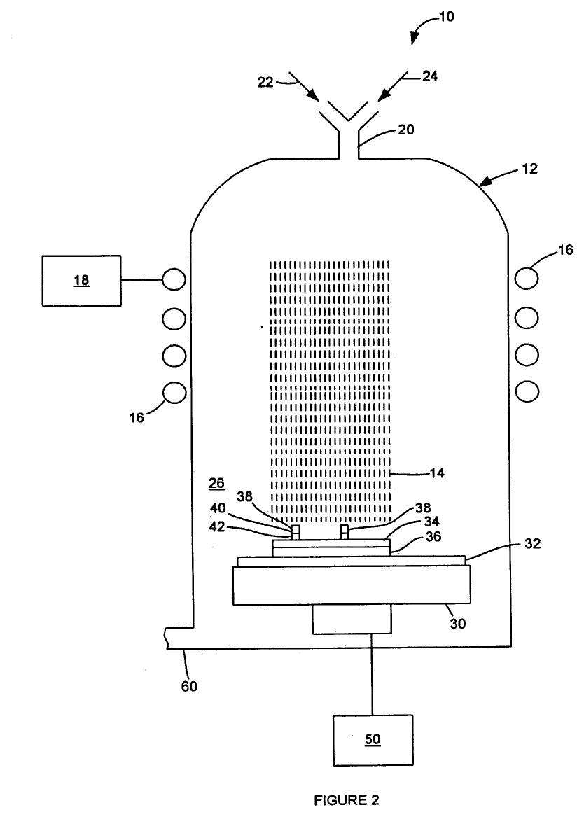

Turning again to the figures, wherein like components may be designated with like reference numbers throughout the various figures, attention is immediately directed to FIG. 2 is a diagrammatic view, in elevation, of a system that is configured according to the present disclosure, generally indicated by the reference number 10, for selectively removing silicon nitride in the presence of silicon dioxide. The system includes a plasma source 12, that is diagrammatically illustrated, for generating a plasma 14 (diagrammatically shown) that is suitable for use in an etching process. By way of example, the plasma source may use an inductively coupled configuration. One such suitable plasma source is described in U.S. Pat. No. 6,143,129 which is incorporated herein by reference. Accordingly, an induction coil 16 couples RF energy into the source vessel from a first RF power supply 18 through a matching network which is not shown. A gas inlet 20 is configured for introducing a combination of a fluorine containing gas 22, as will be further described, and ammonia (NH₃) gas 24 into the plasma source. A processing chamber 26 is located below plasma source 12 and includes a pedestal 30 that supports a workpiece 32 such as, for example, a semiconductor wafer. The workpiece supports a silicon nitride region 34 which overlies a silicon dioxide region 36, the dimensions of which are greatly exaggerated for illustrative purposes. Gate arrangements 38 each include a gate electrode 40 with an underlying layer of silicon dioxide 42, that is supported on silicon nitride region 34. By way of example, it is desired to remove silicon nitride region 34 using plasma 14, except for those portions which are directly below gate arrangements 38. A second RF power source 50 can provide RF power to pedestal 30, generally at one of the ISM (Industry, Scientific, Medical) standard frequencies (i.e., 13.56 MHz, 27.12 MHz or 40.68 MHz. Power source 50 biases the pedestal appropriately, for example, to enhance anisotropic etching. An exhaust port 60 is provided for pumping purposes in maintaining process pressure and removal of process by-products.

Still referring to FIG. 2, in one embodiment, fluorine containing gas 22 is sulfur hexafluoride (SF₆), along with ammonia (NH₃) 24 and any suitable additives such as, for example, argon or nitrogen, as will be discussed immediately hereinafter.

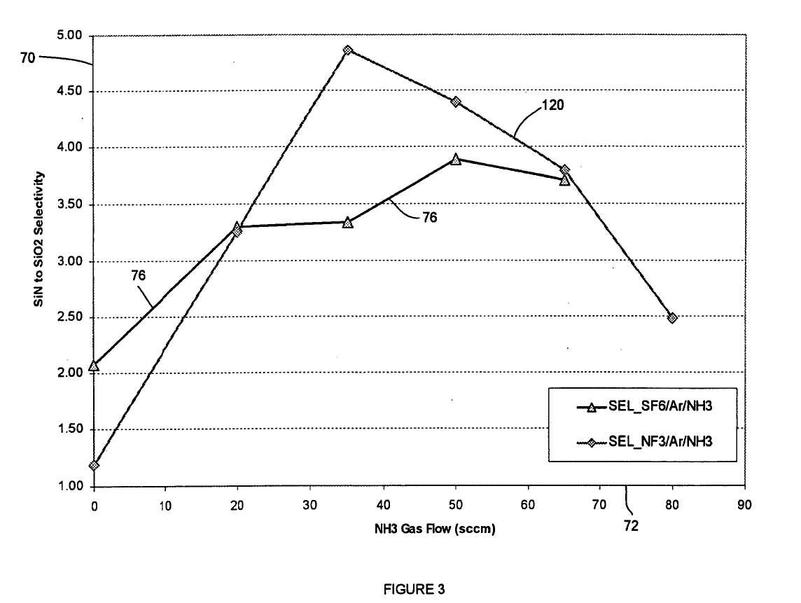

Turning to FIG. 3, in conjunction with FIG. 2, a vertical axis 70, in FIG. 3, represents the silicon nitride to silicon dioxide selectivity, while a horizontal axis 72 represents the flow of ammonia gas. A plot 76 represents the selectivity that is obtained using 30 sccm of SF₆ for a flow rate of ammonia that ranges from 0-65 sccm. A selected set of supporting process conditions include argon gas at a flow rate of 170 sccm, a pressure of 20 millitorr, RF power applied to induction coil 16 by source 18 at a value of at least approximately 1000 watts, zero power applied to pedestal 30, a process temperature of 25 degrees centigrade and a process duration of 30 seconds. It should be appreciated that a peak is presented by plot 76 at an ammonia flow rate of approximately 50 sccm. This suggests that an approximately 5 to 3 ratio of flow of NH₃ to SF₆ achieves near optimized process conditions, at least when using the selected set of process conditions described above. In one embodiment, the ratio of ammonia flow to SF₆ flow can be from greater than zero to 4. That is, acceptable selectivity can be achieved in this range, depending upon other factors that come into play. For example, higher pressure generally enhances selectivity, as is confirmed by the various plots discussed hereinafter. At the same time, however, increasing processing pressure is generally accompanied by a reduction in directionality. That is, the process shifts from some level of anisotropic behavior to being more isotropic (i.e., less directional).

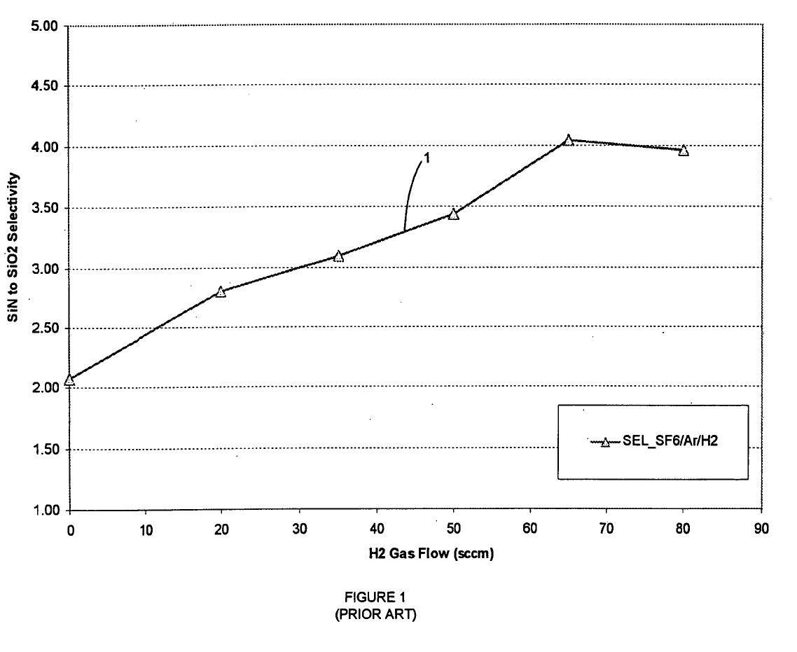

When plot 76 is compared with plot 1 of FIG. 1, it is seen that selectivity is enhanced, over the values that are achieved with the prior art combination of SF₆ and H₂ for values of NH3 gas flow ranging from greater than zero sccm to just slightly less than 60 sccm. Thus, in one embodiment, the flow of ammonia can be in the range from greater that zero up to approximately 60 sccm or a ratio of ammonia to SF₆ flow from greater than zero up to approximately double the flow of SF₆. In this regard, it should be appreciated that all other process conditions are unchanged. That is, the same selected set of supporting process conditions was used for purposes of generating plot 1 of FIG. 1.

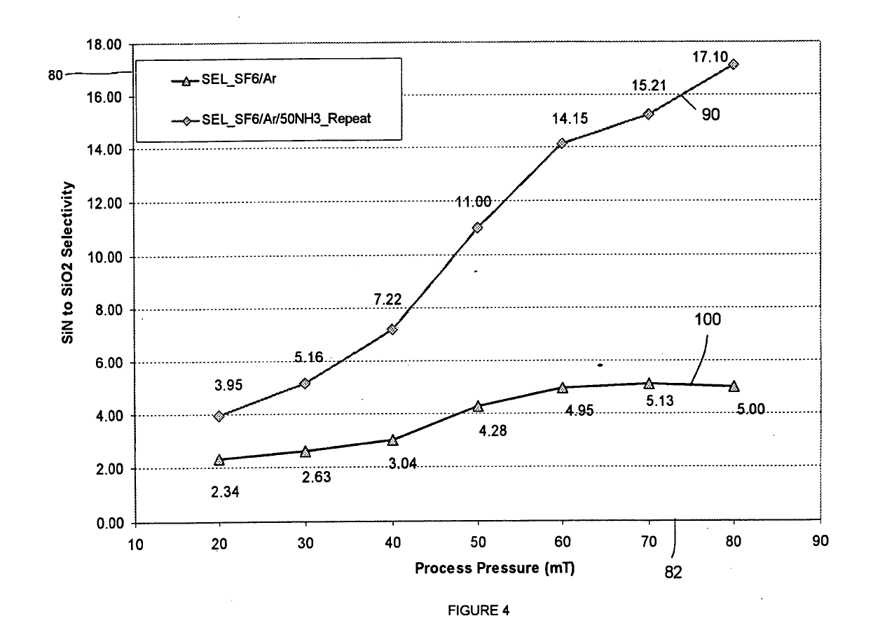

FIG. 4 includes a vertical axis 80, which represents the silicon nitride to silicon dioxide selectivity, while a horizontal axis 82 represents process pressure in millitorr. It is noted that, for each plot in FIG. 4, the measured selectivity value is given, adjacent to each data point. A plot 90 represents the selectivity that is obtained using process conditions that are identical to those which were used in relation to plot 76 of FIG. 3, but with pressure as a variable instead of ammonia flow. For purposes of the present example, 30 sccm of SF₆ and 50 sccm of NH₃ where chosen. The selected set of supporting process conditions again include argon gas at a flow rate of 170 sccm, RF power applied to induction coil 16 by source 18 at a value of at least approximately 1000 watts, zero power applied to pedestal 30, a process temperature of 25 degrees centigrade and a process duration of 30 seconds. It should be appreciated that the various plots herein may have been generated from different process runs and, therefore, some variation in the results is to be expected from plot to plot.

Still referring to FIG. 4, a process run 100 was performed using SF₆ without NH₃ and with all other process conditions being identical to those which were used in the process run that generated plot 90. In this case, plot 100 demonstrates a relatively dramatic reduction in selectivity, which establishes that the ammonia, in cooperation with sulfur hexafluoride, is indeed the responsible agent in terms of the enhanced selectivity that is associated with plot 90.

Turning to FIGS. 2 and 3, in another embodiment, fluorine containing gas 22 is nitrogen trifluoride (NF₃), along with ammonia (NH₃) 24 and any suitable additives such as, for example, argon or nitrogen, as will be further discussed below. A plot 120 in FIG. 3 represents the selectivity that is obtained using 30 sccm of NF₃ for a flow rate of ammonia that ranges from 0-80 sccm. Once again, the selected set of supporting process conditions include argon gas at a flow rate of 170 sccm, a pressure of 20 mT, RF power applied to induction coil 16 by source 18 at a value of at least approximately 1000 watts, zero power applied to pedestal 30, a process temperature of 25 degrees centigrade and a process duration of 30 seconds. It should be appreciated that a peak is presented by plot 120 at an ammonia flow rate of approximately 35 sccm, which is just slightly above the 30 sccm flow rate of the NF₃. This suggests that near equal flow rates of NF₃ and NH₃ result in near optimized process conditions. This optimization should available, at least within a reasonable approximation, over a relatively wide range of variations in the supporting process conditions.

When plot 120 is compared with plot 1 of FIG. 1, it is seen that selectivity is enhanced over the values that are achieved with the prior art combination of SF₆ and NH₃ for values of H₂ or NH₃ gas flows ranging from approximately 13 sccm to 62 sccm and, certainly, over the range of 20 to 60 sccm. In this regard, it should be appreciated that all other process conditions are unchanged. That is, the same selected set of supporting process conditions was used for purposes of generating plot 1 of FIG. 1. Further, for the optimized process, the selectivity is enhanced by approximately 45%, at the same flow of ammonia and with all other conditions being the same. It should also be appreciated that the optimized process conditions for the use of SF₆ and H₂ are obtained at a flow rate of H₂ that is above 60 sccm and results in a selectivity of just slightly over 4.0. When optimized process conditions are compared between NF₃/NH₃ and SF₆ and H₂, the former provides approximately a 20% improvement, while avoiding the aforedescribed problems that are associated with the use of hydrogen gas. In one embodiment, the ratio of flow of NF₃ to NH₃ can be in the range from approximately 0.4 to 2.0, which can provide selectivity that is enhanced with respect to the use of an SF₆/H₂ process. In another embodiment, the ratio of flow of NF₃ to NH₃ can be in the range from approximately 0.4 to 3.5. Again, the selection of particular process conditions such as, for example, pressure can enhance selectivity, however, directionality should also be maintained at a suitable level.

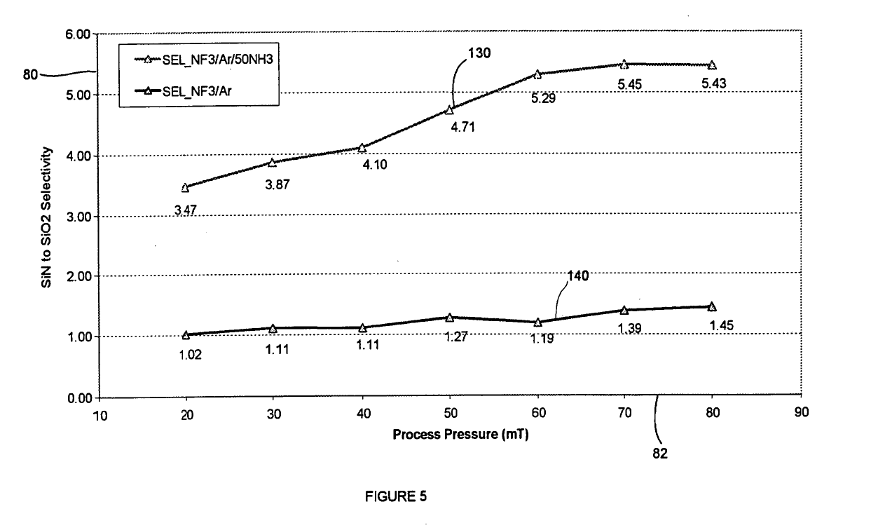

Referring to FIG. 5, a plot 130 represents the selectivity that is obtained using process conditions that are identical to those which were used in relation to plot 120 of FIG. 3, but with pressure as a variable instead of ammonia flow. These process conditions include 30 sccm of NF₃ and 50 sccm of NH₃. The selected set of supporting process conditions again include argon gas at a flow rate of 170 sccm, RF power applied to induction coil 16 by source 18 at a value of at least approximately 1000 watts, zero power applied to pedestal 30, a process temperature of 25 degrees centigrade and a process duration of 30 seconds. A process run 140 was performed using NF₃ without NH₃ and with all other process conditions being identical to those which were used in the process runs that generated plots 120 (FIG. 3) and 130. In this case, plot 140 demonstrates a relatively dramatic reduction in selectivity which establishes that the ammonia is indeed the responsible agent in terms of the enhanced selectivity that is associated with plots 120 and 130.

It should be appreciated that the additive gases such as, for example, argon and nitrogen are not introduced for purposes of affecting the etching process itself, but rather for purposes of stabilizing plasma 14, dependent upon the particular plasma source that is in use. In this regard, it has been empirically demonstrated that reduction in argon flow produces no appreciable difference in selectivity. Further, combinations of sulfur hexafluoride and nitrogen trifluoride, along with ammonia, may be used for purposes of achieving high selectivity.

While a number of exemplary aspects and embodiments have been discussed above, those of skill in the art will recognize certain modifications, permutations, additions and sub-combinations thereof. For example, it is considered that one of ordinary skill in the art may use sulfur hexafluoride and nitrogen trifluoride together and in combination with ammonia for purposes of achieving high selectivity of silicon nitride relative to silicon dioxide, based on the foregoing teachings. It is therefore intended that the following appended claims and claims hereafter introduced are interpreted to include all such modifications, permutations, additions and sub-combinations as are within their true spirit and scope.

1. A dry etching method, comprising:
providing a workpiece that supports silicon nitride and silicon dioxide; and
exposing the workpiece to a plasma containing (i) at least a selected one of sulfur hexafluoride and nitrogen trifluoride and (ii) ammonia to selectively etch the silicon nitride in relation to the silicon dioxide with a given selectivity and introducing no other gases into the plasma which would produce an appreciable effect on the given selectivity.

2. The method of claim 1 comprising:
introducing at least one additive gas into said plasma for stabilizing said plasma.

3. The method of claim 2 including adding at least one of argon and nitrogen to said plasma as said additive gas.

4. The method of claim 3 including forming said plasma from an input gas flow of approximately 30 sccm of nitrogen trifluoride, 170 sccm of argon, and 35 sccm of ammonia.

5. The method of claim 3 including forming said plasma from an input gas flow consisting of 30 sccm of nitrogen trifluoride, 170 sccm of argon, and 35 sccm of ammonia.

6. The method of claim 1 including forming said plasma from an input gas flow including nitrogen trifluoride and ammonia and having a ratio of the flow of ammonia to nitrogen trifluoride in a range from approximately 0.4 to 3.5.

7. The method of claim 1 including forming said plasma from an input gas flow including nitrogen trifluoride and ammonia and having a ratio of the flow of ammonia to nitrogen trifluoride in a range from approximately 0.4 to 2.0.

8. The method of claim 1 including forming said plasma from an input gas flow including approximately equal flows of nitrogen trifluoride and ammonia.

9. The method of claim 3 including forming said plasma from an input gas flow of approximately 30 sccm of sulfur hexafluoride, 170 sccm of argon, and 50 sccm of ammonia.

10. The method of claim 3 including forming said plasma from an input gas flow consisting of approximately 30 sccm of sulfur hexafluoride, 170 sccm of argon, and 50 sccm of ammonia.

11. The method of claim 1 including forming said plasma from an input gas flow including sulfur hexafluoride and ammonia and having a ratio of the flow of ammonia to sulfur hexafluoride in a range from greater than zero to 4.

12. The method of claim 1 including forming said plasma from an input gas flow including sulfur hexafluoride and ammonia and having a ratio of the flow of ammonia to sulfur hexafluoride in a range from greater than zero to approximately double the flow of sulfur hexafluoride.

13. The method of claim 1 including forming said plasma from an input gas flow including a ratio of, at least to an approximation, 5 parts of ammonia to 3 parts of sulfur hexafluoride.

14-26. (canceled)

27. The method of claim 2 including forming said plasma from an input gas flow consisting of nitrogen trifluoride, ammonia and argon where said argon serves as the additive gas for stabilizing the plasma.

28. The method of claim 2 including forming said plasma from an input gas flow consisting of sulfur hexafluoride, ammonia and argon where said argon serves as the additive gas for stabilizing the plasma.

29. The method of claim 1 wherein said exposing is performed at a pressure of 20 millitorr.
